(19) United States
(12) Patent Application Publication
(10) Pub. No.: US 2021/0027927 A1
(43) Pub. Date: Jan. 28, 2021

(54) CIRCULATING DEVICE FOR COOLING AND HEATING SUPERCONDUCTING MAGNET COMPONENTS AT A CONTROLLABLE RATE

(71) Applicant: HEFEI INSTITUTES OF PHYSICAL SCIENCE, CHINESE ACADEMY OF SCIENCES, Hefei (CN)

(72) Inventors: Yuntao SONG, Hefei (CN); Yanyu XIE, Hefei (CN); Huan WU, Hefei (CN); Guang SHEN, Hefei (CN); Kun LU, Hefei (CN); Jing WEI, Hefei (CN); Weiyue WU, Hefei (CN); Mingming SHANG, Hefei (CN); Zhonghui YANG, Hefei (CN); Zhirong ZHANG, Hefei (CN)

(21) Appl. No.: 17/039,679

(22) Filed: Sep. 30, 2020

Related U.S. Application Data
(63) Continuation of application No. PCT/CN2019/102023, filed on Aug. 22, 2019.

(30) Foreign Application Priority Data
Aug. 22, 2018 (CN) 201810957661.1

(51) Int. Cl. H01F 6/04; F17C 13/00

(52) U.S. Cl. CPC H01F 6/04; F25B 19/005; F17C 13/007

(57) ABSTRACT

Disclosed is a circulating device for cooling and heating superconducting magnet components at controllable rate, including a liquid nitrogen tank and a vacuum container. A container for accommodating the superconducting magnet component is provided at an upper end of an interior of the vacuum container. First and second pipelines join and then connect to a top of the liquid nitrogen tank through a coiled pipe. A third pipeline and a first branch of a fourth pipeline join and then connect to an inlet of an electric heater. A PID closed loop for temperature control is provided at the electric heater. A main pipeline of the outlet pipeline of the electric heater is connected to an inlet of the container. A second branch of the fourth pipeline, an outlet pipeline of the container and a branch pipeline of the outlet pipeline of the electric heater communicate with atmosphere.

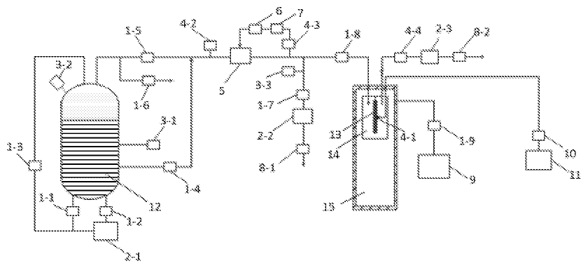

### CROSS-REFERENCE TO RELATED APPLICATIONS

This application is a continuation of International Patent Application No. PCT/CN2019/102023, filed on Aug. 22, 2019, which claims the benefit of priority from Chinese Patent Application No. 201810957661.1, filed on Aug. 22, 2018. The content of the aforementioned applications, including any intervening amendments thereto, is incorporated herein by reference.

### TECHNICAL FIELD

The present application relates to the testing of superconducting magnet components, and more particularly to a circulating device for cooling and heating superconducting magnet components at a controllable rate.

### BACKGROUND

A superconducting magnet is an important and indispensable part in a superconducting tokamak device, and its operational stability is directly related to the operational safety of the whole fusion device. Generally, during the actual operation process, a large-scale superconducting magnet is simultaneously exposed to strong magnetic field, ultra-low temperature and large current, and there are also interactions between them. The insulation for the superconducting magnet generally includes turn-to-turn insulation, pancake-to-pancake insulation and grounding insulation, and the insulating material involved therein is generally prepared from epoxy, glass fiber and polyimide. Before the actual operation, the superconducting magnet is required to be cooled in accordance with a certain gradient, and after the operation is completed, the superconducting magnet is required to be heated at a certain heating rate. Therefore, in the early stage of the manufacturing process, a superconducting magnet component used for qualification is required to be treated in a condition which is analogue to the actual working condition, that is, the superconducting magnet component should be cooled at a certain gradient and heated at a certain heating rate. Therefore, it is important to select suitable and controllable cooling and heating strategies in the qualification of the superconducting magnets.

### SUMMARY

In order to overcome shortcomings in the prior art, this application provides a circulating device for cooling and heating superconducting magnet components at a controllable rate, which simulates the actual operation conditions of the superconducting magnet to perform the cooling at a certain cooling gradient and heating at a certain heating rate, achieving the controllable cooling and heating for the superconducting magnet.

The technical solutions of the application are described as follows.

This application provides a circulating device for cooling and heating a superconducting magnet component at a controllable rate, comprising: a liquid nitrogen tank and a vacuum container;

wherein a container for accommodating the superconducting magnet component is provided at an upper end of an interior of the vacuum container; and a first thermometer is provided on the superconducting magnet component;

a first pipeline, a second pipeline and a third pipeline are provided at a bottom of the liquid nitrogen tank; the first pipeline and the second pipeline join and then are connected to a top of the liquid nitrogen tank through a coiled pipe; a fourth pipeline is led out of the top of the liquid nitrogen tank and is divided into a first branch and a second branch, and the third pipeline and the first branch of the fourth pipeline join and then are connected to an inlet of an electric heater; and the second branch of the fourth pipeline is communicated with an atmosphere; and

a PID closed loop for temperature control is provided at the electric heater; an outlet pipeline of the electric heater is divided into a main pipeline and a branch pipeline, and an end of the branch pipeline is communicated with the atmosphere and the main pipeline is connected to an inlet of the container for accommodating the superconducting magnet component; and an end of an outlet pipeline of the container for accommodating the superconducting magnet component is communicated with the atmosphere.

In an embodiment, the first thermometer is provided at a middle of the superconducting magnet component and sequentially connected to a temperature data logger and a computer through signal lines; a second thermometer is provided at the first branch of the fourth pipeline; a third thermometer is provided at the outlet pipeline of the electric heater; and a fourth thermometer is provided at the outlet pipeline of the container for accommodating the superconducting magnet component.

In an embodiment, the third thermometer, the electric heater, a power regulator and a temperature controller together form the PID closed loop through signal lines.

In an embodiment, a first stop valve is provided at the first pipeline; the second pipeline is provided with a second stop valve and a first ambient air vaporizer in sequence; a third stop valve is provided at the coiled pipe; a fourth stop valve is provided at the third pipeline; a fifth stop valve is provided at the first branch of the fourth pipeline; and a sixth stop valve is provided at the second branch of the fourth pipeline.

In an embodiment, the branch pipeline of the outlet pipeline of the electric heater is provided with a third pressure gauge, a seventh stop valve, a second ambient air vaporizer and a first flow controller in sequence; and the main pipeline of the outlet pipeline of the electric heater is connected to the inlet of the container for accommodating the superconducting magnet component through an eighth stop valve; the outlet pipeline of the container for accommodating the superconducting magnet component is provided with a fourth thermometer, a third ambient air vaporizer and a second flow controller in sequence.

In an embodiment, a body of the vacuum container is connected to a ninth stop valve and a vacuum pumping assembly in sequence.

In an embodiment, a body of the liquid nitrogen tank is provided with a first pressure gauge and a second pressure gauge; the first pressure gauge is configured to measure pressure of liquid nitrogen in the liquid nitrogen tank, and the second pressure gauge is configured to measure pressure of nitrogen gas in the liquid nitrogen tank.

Two cooling sources including cooled nitrogen gas and liquid nitrogen are provided in the application, where the liquid nitrogen is pressed into the output pipelines from the liquid nitrogen tank, and the cooled nitrogen gas having a temperature as low as 110 K is prepared through the steps of: vaporizing liquid nitrogen through the first ambient air vaporizer at the bottom of the liquid nitrogen tank; mixing the vaporized nitrogen and liquid nitrogen coming from the first pipeline to cool the vaporized nitrogen again; and allowing the cooled nitrogen gas to flow towards the top of the liquid nitrogen tank through the coiled pipe.

In an early stage of the test, the superconducting magnet component is cooled to about 110 K with the cooled nitrogen gas, and then the cooling source output channel is switched to the liquid nitrogen pipe to further cool the superconducting magnet component to 77 K. In order to effectively control the cooling and heating rates of the superconducting magnet component, liquid nitrogen in the liquid nitrogen tank is required to be sufficient and pressure of the cooled nitrogen gas in the liquid nitrogen tank is required to be kept within a certain range before the test. Since the flow of the cooled nitrogen gas in the main pipeline is required to be maintained within a certain range, the application provides a cooling structure in which the main pipeline and the branch pipeline assist each other. Moreover, the application also uses two sets of flow control systems to respectively control the flow of the main pipeline and the branch pipeline efficiently, which makes the cooled nitrogen gas in the main pipeline and the branch pipeline cooperate with each other, thereby ensuring that the flow of the cooled nitrogen gas flowing through the superconducting magnet component during the test is maintained within a certain range.

The electric heater, the power regulator, the temperature controller and the third thermometer, which are provided on the main pipeline, together form the PID closed loop, which serves as a temperature control system for heating and cooling the superconducting magnet component. The third thermometer is provided at the main pipeline between the electric heater and the container for accommodating the superconducting magnet component. The temperature of the inlet of the container for accommodating the superconducting magnet component is measured by the third thermometer in real time and compared with a preset value of the temperature controller to allow the obtained control signals to be sent to the power regulator, which adjusts the power of the electric heater to adjust the cooling rate, the heating rate and a temperature of the cooled nitrogen gas. Throughout the heating and cooling cycle, a difference between temperatures of the inlet and the outlet of the container for accommodating the superconducting magnet component is controlled to control the maximum temperature gradient of the superconducting magnet component in the container for accommodating the superconducting magnet component, so as to ensure that the maximum temperature gradient of each part of the superconducting magnet component does not exceed the required value, otherwise, the cooling or heating rate is required to be reduced.

This application has the following advantages.

In the application, nitrogen gas obtained by heating liquid nitrogen through the first ambient air vaporizer at the bottom of the liquid nitrogen tank is cooled again with liquid nitrogen to ensure that the cooled nitrogen gas in the liquid nitrogen tank meets temperature requirements of the cooling and heating cycling test. A container for accommodating the superconducting magnet component is provided in the vacuum container, and enables multiple superconducting magnet components to be simultaneously accommodated for the cooling and heating cycling test. Two output pipelines are provided at the cooling source to convey cooled nitrogen gas and liquid nitrogen, respectively. Based on the design in which the main pipeline and the branch pipeline assist each other, the flow and pressure of the cooled nitrogen gas in the main pipeline are effectively kept at a certain value, respectively. The temperature of cooled nitrogen gas at the inlet of the container for accommodating the superconducting magnet component is accurately controlled through a heating system, and is compared with the temperature of cooled nitrogen gas at the outlet of the container for accommodating the superconducting magnet component to ensure the temperature difference to be within a certain range, thereby cooling the superconducting magnet component to 77 K from the room temperature at a certain cooling rate and heating the superconducting magnet component to the room temperature again from 77 K.

### BRIEF DESCRIPTION OF THE DRAWINGS

The FIGURE is a schematic diagram of a circulating device for cooling and heating superconducting magnet components at a controllable rate of the present application.

### DETAILED DESCRIPTION OF EMBODIMENTS

This application provides a circulating device for cooling and heating a superconducting magnet component at a controllable rate, as shown in the FIGURE, including a liquid nitrogen tank 12 and a vacuum container 15. A container 14 for accommodating the superconducting magnet component is provided at an upper end of an interior of the vacuum container 15. A first thermometer 4-1 is provided at a middle of a superconducting magnet component 13 and sequentially connected to a temperature data logger 10 and a computer 11 which are provided outside the container 14. A first pipeline, a second pipeline and a third pipeline are provided at a bottom of the liquid nitrogen tank 12. A first stop valve 1-1 is provided at the first pipeline. The second pipeline is provided with a second stop valve 1-2 and a first ambient air vaporizer 2-1 in sequence. The first pipeline and the second pipeline join and then are connected to a top of the liquid nitrogen tank 12 through a coiled pipe. A third stop valve 1-3 is provided at the coiled pipe. A fourth stop valve 1-4 is provided at the third pipeline. A fourth pipeline is led out of the top of the liquid nitrogen tank 12 and is divided into a first branch and a second branch which is communicated with the atmosphere. A fifth stop valve 1-5 is provided at the first branch of the fourth pipeline. The third pipeline and the first branch of the fourth pipeline join and then are connected to an inlet of an electric heater 5. A sixth stop valve 1-6 is provided at the second branch of the fourth pipeline.

A body of the liquid nitrogen tank 12 is provided with a first pressure gauge 3-1 and a second pressure gauge 3-2. The first pressure gauge 3-1 is configured to measure pressure of liquid nitrogen in the liquid nitrogen tank 12. The second pressure gauge 3-2 is configured to measure pressure of nitrogen in the liquid nitrogen tank 12.

A second thermometer 4-2 is provided at the first branch of the fourth pipeline. A third thermometer 4-3 is provided at an outlet pipeline of the electric heater. The electric heater 5, the third thermometer 4-3, a power regulator 6 and a temperature controller 7 together form a PID closed loop for temperature control. The outlet pipeline of the electric heater is divided into a main pipeline and a branch pipeline. The branch pipeline is provided with a third pressure gauge 3-3, a seventh stop valve 1-7, a second ambient air vaporizer 2-2 and a first flow controller 8-1 in sequence and is communicated with the atmosphere at an end of the branch pipeline. The main pipeline is connected to an inlet of the container 14 through an eighth stop valve 1-8. An outlet pipeline of the container 14 is provided with a fourth thermometer 4-4, a third ambient air vaporizer 2-3 and a second flow controller 8-2 in sequence, and is communicated with the atmosphere at the end of the outlet pipeline of the container 14. A body of the vacuum container 15 is connected to a ninth stop valve 1-9 and a vacuum pumping assembly 9 in sequence.

The heating and cooling cycling test is implemented through the following steps.

The first pressure gauge 3-1 and the second pressure gauge 3-2 are checked to ensure that an interior of the liquid nitrogen tank 12 has sufficient liquid nitrogen and nitrogen gas in the interior of the liquid nitrogen tank 12 has a certain pressure. The vacuum pumping assembly 9 and the ninth stop valve 1-9 are turned on to vacuumize the vacuum container 15. When a vacuum degree of the vacuum container 15 is less than 0.1 Pa, the fourth stop valve 1-4, the sixth stop valve 1-6, the eighth stop valve 1-8 and the second flow controller 8-2 are closed, and the third stop valve 1-3, the fifth stop valve 1-5 and the seventh stop valve 1-7 are opened. The first stop valve 1-1 and the second stop valve 1-2 are adjusted to maintain a pressure of nitrogen gas in the liquid nitrogen tank 12 within a certain range. The pressure of the nitrogen gas flowing through the electric heater 5 is kept within a certain range by controlling the sixth stop valve 1-6, the first flow controller 8-1 and observing the third pressure gauge 3-3.

When the temperature displayed by the second thermometer 4-2 is less than 110 K and is basically kept within a certain range, parameters of the temperature controller 7 are set, and the electric heater 5 and the power regulator 6 are turned on to allow nitrogen gas in the pipelines to be rapidly heated to the room temperature and kept at the room temperature for several minutes under the control of PID. The eighth stop valve 1-8 is opened, and the second flow controller 8-2 and the first flow controller 8-1 are controlled to maintain the flow in the pipelines within a certain range.

The parameters of the temperature controller 7 are set to control nitrogen gas flowing into the container 14 to achieve a desired cooling rate and a required temperature. A comparison between temperatures of the inlet and an outlet of the container 14 for accommodating the superconducting magnet component is made in real time to ensure the temperature difference to be within a certain range.

A surface temperature of the superconducting magnet component 13 is collected by the temperature data logger 10 and observed in real time through the computer 11. When the temperature of the inlet of the container 14 is decreased to about 110 K, the fifth stop valve 1-5, the sixth stop valve 1-6, the first stop valve 1-1 and the second stop valve 1-7 are closed and the fourth stop valve 1-4 is opened to decrease the temperature of the inlet of the container 14 to about 77 K. The fourth stop valve 1-4 is closed, and the fifth stop valve 1-5, the sixth stop valve 1-6, the seventh stop valve 1-7, the first stop valve 1-1 and the second stop valve 1-2 are opened, and the parameters of the temperature controller 7 are set to heat the superconducting magnet component 13 to the room temperature at a certain rate.

What is claimed is:

1. A circulating device for cooling and heating a superconducting magnet component at a controllable rate, comprising: a liquid nitrogen tank and a vacuum container;
wherein a container for accommodating the superconducting magnet component is provided at an upper end of an interior of the vacuum container; and a first thermometer is provided on the superconducting magnet component;
a first pipeline, a second pipeline and a third pipeline are provided at a bottom of the liquid nitrogen tank; the first pipeline and the second pipeline join and then are connected to a top of the liquid nitrogen tank through a coiled pipe; a fourth pipeline is led out of the top of the liquid nitrogen tank and is divided into a first branch and a second branch, and the third pipeline and the first branch of the fourth pipeline join and then are connected to an inlet of an electric heater; and the second branch of the fourth pipeline is communicated with an atmosphere; and
a PID closed loop for temperature control is provided at the electric heater; an outlet pipeline of the electric heater is divided into a main pipeline and a branch pipeline, and an end of the branch pipeline is communicated with the atmosphere and the main pipeline is connected to an inlet of the container for accommodating the superconducting magnet component; and an end of an outlet pipeline of the container for accommodating the superconducting magnet component is communicated with the atmosphere.

2. The circulating device of claim 1, wherein the first thermometer is provided at a middle of the superconducting magnet component and sequentially connected to a temperature data logger and a computer through signal lines; a second thermometer is provided at the first branch of the fourth pipeline; a third thermometer is provided at the outlet pipeline of the electric heater; and a fourth thermometer is provided at the outlet pipeline of the container for accommodating the superconducting magnet component.

3. The circulating device of claim 2, wherein the third thermometer, the electric heater, a power regulator and a temperature controller together form the PID closed loop through signal lines.

4. The circulating device of claim 1, wherein a first stop valve is provided at the first pipeline; the second pipeline is provided with a second stop valve and a first ambient air vaporizer in sequence; a third stop valve is provided at the coiled pipe; a fourth stop valve is provided at the third pipeline; a fifth stop valve is provided at the first branch of the fourth pipeline; and a sixth stop valve is provided at the second branch of the fourth pipeline.

5. The circulating device of claim 1, wherein the branch pipeline of the outlet pipeline of the electric heater is provided with a third pressure gauge, a seventh stop valve, a second ambient air vaporizer and a first flow controller in sequence; and the main pipeline of the outlet pipeline of the electric heater is connected to the inlet of the container for accommodating the superconducting magnet component through an eighth stop valve; the outlet pipeline of the container for accommodating the superconducting magnet component is provided with a fourth thermometer, a third ambient air vaporizer and a second flow controller in sequence.

6. The circulating device of claim 1, wherein a body of the vacuum container is connected to a ninth stop valve and a vacuum pumping assembly in sequence.

7. The circulating device of claim 1, wherein a body of the liquid nitrogen tank is provided with a first pressure gauge and a second pressure gauge; the first pressure gauge is configured to measure pressure of liquid nitrogen in the liquid nitrogen tank, and the second pressure gauge is configured to measure pressure of nitrogen gas in the liquid nitrogen tank.
